(19) United States
(12) Patent Application Publication
(10) Pub. No.: US 2014/0069479 A1
(43) Pub. Date: Mar. 13, 2014

(54) Photoelectric Device Module and Manufacturing Method Thereof

(71) Applicant: SAMSUNG SDI CO., LTD., Yongin-si (KR)

(72) Inventors: Jung-Yup Yang, Yongin-si (KR); Young-Kyoung Ahn, Yongin-si (KR); Min-Gu Kim, Yongin-si (KR); Jun-Young Lee, Yongin-si (KR); Min Park, Yongin-si (KR); Pil-Ho Huh, Yongin-si (KR); Yeon-Il Kang, Yongin-si (KR); Hyun-Young Cho, Yongin-si (KR)

(73) Assignee: SAMSUNG SDI CO., LTD., Yongin-si (KR)

(21) Appl. No.: 13/829,224

(22) Filed: Mar. 14, 2013

Related U.S. Application Data
(60) Provisional application No. 61/699,685, filed on Sep. 11, 2012.

(51) Int. Cl. H01L 31/02

(52) U.S. Cl. CPC H01L 31/0201
USPC 136/244; 438/66

(57) ABSTRACT

A solar cell module according to the present invention includes photoelectric converting cells, interconnect wiring, and a bus bar, wherein the interconnect wiring is attached by a conductive adhesive layer, and the bus bar is attached by an insulating adhesive layer. A method for manufacturing the solar cell module includes attaching the interconnect wiring and the bus bar by the conductive adhesive layer and the insulating adhesive layer, and according to the method, a solar cell module with excellent characteristics can be manufactured through a simple and inexpensive method.

### CROSS-REFERENCE TO RELATED APPLICATION

This application claims priority to and the benefit of U.S. Provisional Application No. 61/699,685, filed on Sep. 11, 2012 in the U.S. Patent and Trademark Office, the entire content of which is incorporated herein by reference.

### BACKGROUND

1. Field

The described technology relates generally to a solar cell module and a manufacturing method thereof.

2. Description of the Related Art

A solar cell is a photovoltaic conversion device for converting light energy of the sun into electrical energy by using the photovoltaic effect. In general, a solar cell module used for a sunlight electric generator system and an electric device includes a plurality of photoelectric converting cells coupled in series. A current generated by the electrically connected photoelectric converting cells is collected by module wiring formed on the solar cell module and is then transmitted to a junction box. The above information disclosed in this Background section is only for enhancement of understanding of the background of the described technology and therefore it may contain information that does not form the prior art that is already known in this country to a person of ordinary skill in the art.

### SUMMARY

The described technology has been made in an effort to provide a solar cell module for preventing current leakage, providing excellent durability, and allowing an excellent effect with a low cost through a simple and easy process, and a manufacturing method thereof.

According to the method for manufacturing the solar cell module of the present exemplary embodiment, the solar cell module for generating an excellent effect with a low cost by using a simple and easy process can be manufactured.

Further, according to the present exemplary embodiment, a solar cell module without current leakage and with excellent durability is acquired.

### BRIEF DESCRIPTION OF THE DRAWINGS

FIG. 1 shows a top plan view of a solar cell module according to an exemplary embodiment.

FIG. 2 shows a cross-sectional view with respect to a line II-II of FIG. 1.

FIG. 3 shows a cross-sectional view with respect to a line III-III of FIG. 1.

FIG. 4 shows a cross-sectional view with respect to a line IV-IV of FIG. 1.

FIG. 5 shows a graph for a damp heat test result according to an exemplary embodiment.

FIG. 6A to 6F show a method for manufacturing a solar cell module according to an exemplary embodiment, magnifying a part VI of FIG. 1.

FIG. 7 is a flow chart illustrating the process of a method for fabricating a solar cell module according to an embodiment.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

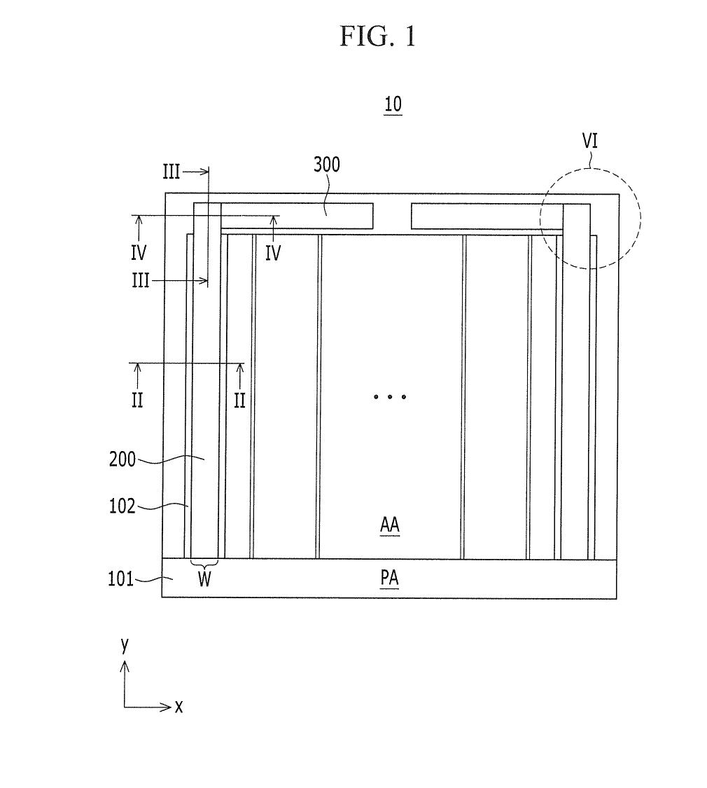

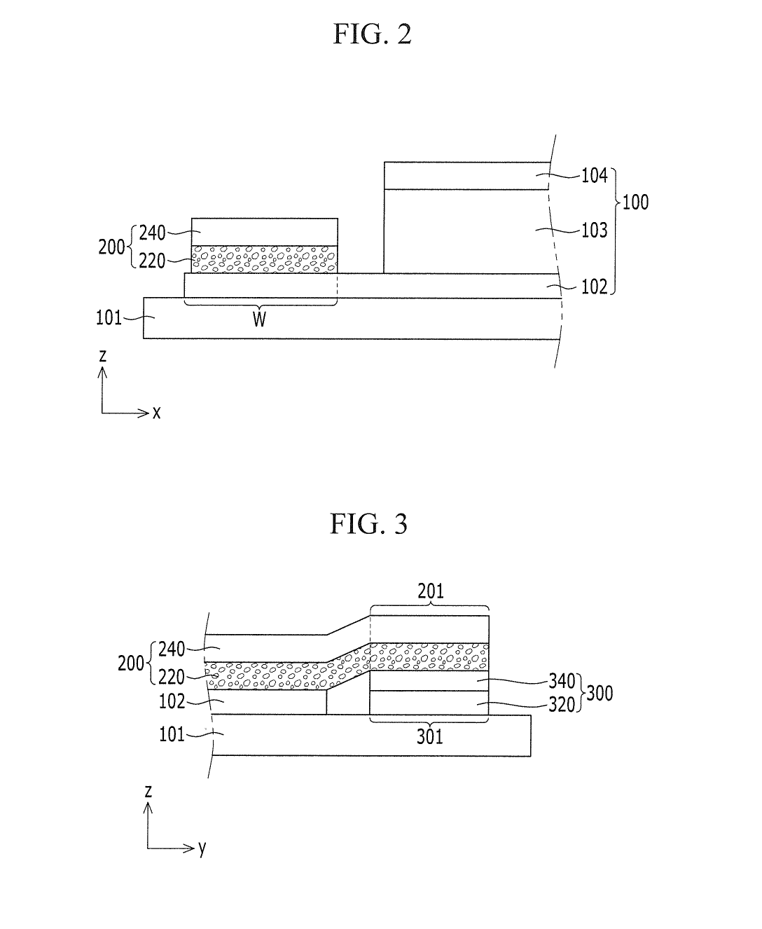

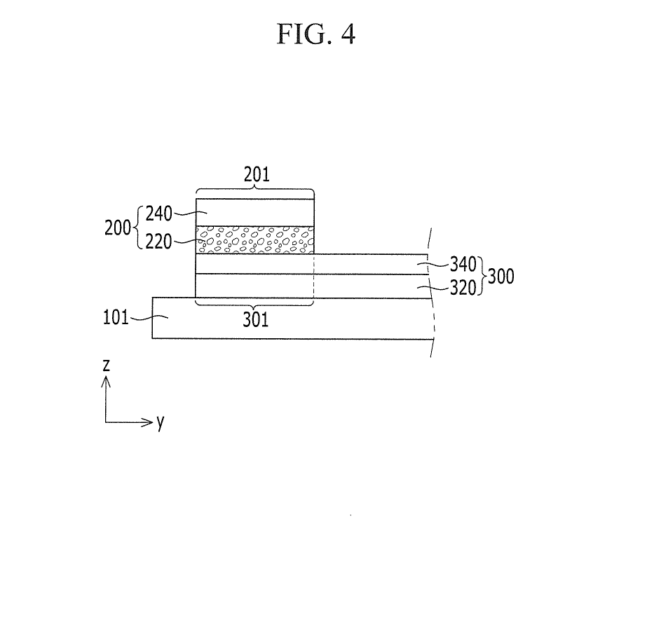

FIG. 1 shows a top plan view of a solar cell module according to an exemplary embodiment, FIG. 2 shows a cross-sectional view with respect to a line II-II of FIG. 1, FIG. 3 shows a cross-sectional view with respect to a line III-III of FIG. 1, and FIG. 4 shows a cross-sectional view with respect to a line IV-IV of FIG. 1.

Referring to FIG. 1 to FIG. 3, the solar cell module 10 includes a substrate 101, a plurality of photoelectric converting cells 100, interconnect wiring 200, and a bus bar 300.

The substrate 101 includes an active area (AA) in which a plurality of photoelectric converting cells 100 are formed, and a periphery area (PA) which surrounds the active area (AA) and in which the bus bar 300 is formed. The substrate 101 may be formed with various materials including plate-type glass, ceramic, stainless steel, metal, or film-type polymers.

The photoelectric converting cells 100 are formed in the active area (AA). The photoelectric converting cells 100 may be extended in a first direction (y-axis direction of FIG. 1) of the substrate 101, and may be coupled in series in a second direction (x-axis direction of FIG. 1) crossing the first direction. Each photoelectric converting cell 100 includes a rear electrode layer 102, a light absorbing layer (or photoelectric converting layer) 103, and a transparent electrode layer 104 located on the substrate 101.

The rear electrode layer 102 is provided on the substrate 101. The rear electrode layer 102 is made of a metal with excellent optical reflective efficiency and excellent adhesion to the substrate 101. For example, the rear electrode layer 102 includes molybdenum (Mo). The molybdenum (Mo) has high electrical conductivity, forms an ohmic contact with the photoelectric converting layer 103, and is stable during a high temperature heat treatment for forming the photoelectric converting layer 103.

The photoelectric converting layer 103 is provided over the rear electrode layer 102. The photoelectric converting layer 103 is made of either silicon or a compound semiconductor. For example, the photoelectric converting layer 103 may have a semiconductor pn junction or a pin junction structure. Therefore, the photoelectric converting layer 103 includes a p-type semiconductor layer and an n-type semiconductor layer, and an intrinsic semiconductor layer may be inserted between the p-type semiconductor layer and the n-type semiconductor layer. Also, when the photoelectric converting layer 103 is made of a compound semiconductor, it may be formed with at least one material of CIGS, CIS, CGS, and CdTe. For example, the photoelectric converting layer 103 is formed with at least one material selected from the group of CdTe, CuInSe₂, Cu(In, Ga)Se₂, Cu(In, Ga)(Se, S)₂, Ag(InGa)Se₂, Cu(In, Al)Se₂, and CuGaSe₂.

The transparent electrode layer 104 is provided over the photoelectric converting layer 103. The transparent electrode layer 104 may be formed with a metal oxide including boron doped zinc oxide (BZO), zinc oxide (ZnO), indium oxide (In₂O₃), and indium tin oxide (ITO) with excellent light transmittance. The transparent electrode layer 104 has great electrical conductivity and great light transmittance.

The current generated by the photoelectric converting cell 100 is collected by the interconnect wiring 200. The interconnect wiring 200 is electrically connected to the photoelectric converting cell 100 formed in the outermost region of the active area (AA). Referring to FIG. 2, for a connection to the interconnect wiring 200, a wiring connector (W) formed by partially exposing the rear electrode layer 102 is formed on the photoelectric converting cell 100 formed in the outermost region

The interconnect wiring 200 includes a wiring metal layer 240 for collecting the current, and a conductive adhesive layer 220 for adhering the wiring metal layer 240 to the wiring connector (W) of the rear electrode layer 102 and turning them on. That is, the interconnect wiring 200 may be a conductive metal tape including the conductive adhesive layer 220. In one embodiment, the interconnect wiring 200 further includes a black cover layer made of a black polyethylene terephthalate (PET) film on the wiring metal layer 240 for the purpose of improving the outer appearance.

The wiring metal layer 240 may be a metal foil or a metal ribbon made of copper (Cu), copper (Cu)/tin (Sn), aluminum (Al), lead (Pb), silver (Ag), or an alloy thereof. A thickness of the wiring metal layer 240 may be between about 30 and about 400 μm. The wiring metal layer 240 is thicker than about 30 μm in order to secure electric conductivity, and a thicker wiring metal layer 240 generally better prevents power loss, although the thickness of the wiring metal layer 240 is about 400 μm or less. When the wiring metal layer 240 is thicker than 400 μm, only the costs are increased without any further improvement to power loss.

The conductive adhesive layer 220 includes conductive particles, and an adhesive in which the conductive particle are spread. The conductive particles may be metal particles including at least one of copper (Cu), silver (Ag), gold (Au), iron (Fe), nickel (Ni), lead (Pb), zinc (Zn), cobalt (Co), titanium (Ti), and magnesium (Mg), or plating particles caused by them. The conductive particle may have a diameter of between about 10 and 100000 nm depending on acquisition of conductivity and maintenance of adhesiveness. When the diameter of a conductive particle is less than 10 nm, it is difficult to acquire sufficient conductivity, but when the diameter of the conductive particle is larger than 100000 nm, the adhesiveness of the conductive adhesive layer 220 is weak. The adhesive in which the conductive particles are spread is an adhesive layer made of a resin including an acryl-based resin, an epoxy-based resin, a butyl-based resin, ethylvinyl acetate (EVA), polyvinyl butyral (PVB), silicon (Si), ionomer, or polyoxy ethylene (POE).

A thickness of the conductive adhesive layer 220 is set with respect to adhesiveness between the rear electrode layer 102 and the wiring metal layer 240, and contact resistance. For example, the thickness of the conductive adhesive layer 220 may be between about 1 μm and about 500 μm. When the conductive adhesive layer 220 is thinner than about 1 μm, the adhesiveness between the rear electrode layer 102 and the wiring metal layer 240 is weak. However, when the conductive adhesive layer 220 is thicker than about 500 μm, the contact resistance between the rear electrode layer 102 and the wiring metal layer 240 is increased.

The interconnect wiring 200 is adhered to the wiring connector (W) by the conductive adhesive layer 220. That is, the interconnect wiring 200 is adhered to a top of the rear electrode layer 102 exposed in the first direction (y-axis direction of FIG. 1) of the photoelectric converting cell 100 formed in the outermost region of the active area (AA). The current generated by the photoelectric converting cell 100 is collected through the rear electrode layer 102, the conductive adhesive layer 220, and the interconnect wiring 200.

When the interconnect wiring 200 is configured with the wiring metal layer 240 and the conductive adhesive layer 220 for adhering it, the module wiring for collecting the current may be easily formed by adhering the metal tape type of interconnect wiring 200 to the wiring connector (W) without a conventional soldering or welding process.

Referring to FIG. 1 and FIG. 3, the interconnect wiring 200 includes an extended portion 201 further extended in the first direction (y-axis direction of FIG. 1) of the photoelectric converting cell 100 to reach the periphery area (PA). The extended portion 201 is electrically connected to the bus bar 300 formed in the periphery area (PA). Accordingly, the current collected to the interconnect wiring 200 is transmitted to the bus bar 300, and it is then transmitted to a junction box formed outside the solar cell module 10 through the bus bar 300.

The bus bar 300 includes a bus bar metal layer 340 and an insulating adhesive layer 320 for adhering the bus bar metal layer 340 to the substrate 101. That is, the bus bar 300 may be an insulating metal tape including the insulating adhesive layer 320.

The bus bar metal layer 340 may be a metal foil or a metal ribbon made of copper (Cu), copper (Cu)/tin (Sn), aluminum (Al), lead (Pb), silver (Ag), or an alloy thereof. The insulating adhesive layer 320 is an adhesive layer made of resin including an acryl-based resin, an epoxy-based resin, a butyl-based resin, ethylvinyl acetate (EVA), polyvinyl butyral (PVB), silicon (Si), an ionomer, and polyoxy ethylene (POE). The thickness of the insulating adhesive layer 320 may be appropriately selected by considering prevention of generation of a leakage current and a step caused by coupling with other components. That is, the insulating adhesive layer 320 may be substantially thicker than 1 μm so as to sufficiently insulate a space between the bus bar metal layer 340 and the substrate 101 and to prevent a current leakage. Also, it may be thinner than 500 μm in consideration of the interconnect wiring 200 and a sealing member.

The bus bar metal layer 340 is adhered to the periphery area (PA) of the substrate 101 by the insulating adhesive layer 320. Therefore, when the current flows to the bus bar metal layer 340, the leakage of current to the substrate 101 is prevented or significantly reduced. The bus bar 300 includes an overlapped portion 301 overlapped on the extended portion 201 of the interconnect wiring 200 and formed on a first end of the bus bar 300. That is, the conductive adhesive portion 220 of the extended portion 201 is adhered to the bus bar metal layer 340 of the overlapped portion 301. Accordingly, the current collected to the interconnect wiring 200 is transmitted to the bus bar metal layer 340 through the conductive adhesive portion 220 and is then transmitted to an external junction box through the bus bar 300.

As described, by configuring the bus bar 300 with the bus bar metal layer 340 and the insulating adhesive layer 320 for adhering it on the substrate 101, the bus bar 300 generating no or only a small amount of leakage current can be formed without an additional insulation process.

Also, according to the present exemplary embodiment, by configuring the adhesive layer of the interconnect wiring 200 with the conductive adhesive layer 220 and the adhesive layer of the bus bar 300 with the insulating adhesive layer 320, conductivity of the interconnect wiring 200 is acquired (i.e., resistance is reduced) and the generation of leakage current by the bus bar 300 is prevented or significantly reduced.

Referring to FIG. 4, the insulating adhesive layer 320, the bus bar metal layer 340, the conductive adhesive layer 220, and the wiring metal layer 240 are sequentially stacked on a region in which the extended portion 201 of the interconnect wiring 200 is overlapped with the overlapped portion 301 of the bus bar 300. Accordingly, the interconnect wiring 200 and the bus bar 300 may be electrically connected to each other, and the bus bar 300 may be sufficiently insulated from the substrate 101. That is, the bus bar 300 can be formed by a simple process, and insulated from the substrate 101 without further processing at the same time, so as to substantially prevent generation of the leakage current, since the bus bar 300 is attached to the substrate 101 by the insulating adhesive layer 320. Further, the interconnect wiring 200 can be formed by a simple process, and electrically connected to the rear electrode layer 102 and the bus bar 300 without further processing at the same time, since the interconnect wiring 200 is attached to the rear electrode layer 102 and the bus bar 300 by the conductive adhesive layer 220.

Conventionally, both of the interconnect wiring 200 and the bus bar 300 are formed by a conductive metal tape, so as to form the module wirings by a simple process without a soldering or welding process. In this case, however, the leakage current is generated from the bus bar 300. Thus, in order to solve this problem, extra insulating tape must be formed between the bus bar 300 and the substrate 101, so that the additional process attaches the extra insulating tape which increases the entire thickness. On the other hand, according to the present exemplary embodiment, as described above, the interconnect wiring 200 and the bus bar 300 can be formed by a simple process, and at the same time, the generation of the leakage current can be prevented without any extra insulating tape.

Also, according to the present exemplary embodiment, if needed, each of the thickness of the adhesive layers 220 and 320 can be appropriately adjusted without increasing the entire thickness of the region overlapping the extended portion 201 and the overlapped portion 301. For example, when the insulating adhesive layer 320 is thick (e.g., thicker than about 300 μm), thereby providing sufficient insulation between the substrate 101 and the bus bar metal layer 340, the conductive adhesive layer 220 may be thinner (e.g., thinner than about 100 μm) to compensate the increasing thickness of the insulating adhesive layer 320. In this case, the bus bar metal layer 340 is sufficiently insulated from the substrate 101, so that the generation of the leakage current can be prevented without increasing the entire thickness of the region overlapping the interconnect wiring 200 and the bus bar 300. Also, the contact resistance of the interconnect wiring 200 can be decreased by decreasing the transfer distance of electrons through the conductive adhesive layer 220, since the thickness of the conductive adhesive layer 220 is decreased.

Further, the interconnect wiring 200 is adhered by the conductive adhesive layer 220 including the conductive particles, so relatively uniform contact resistance is maintained without much influence by external moisture and heat.

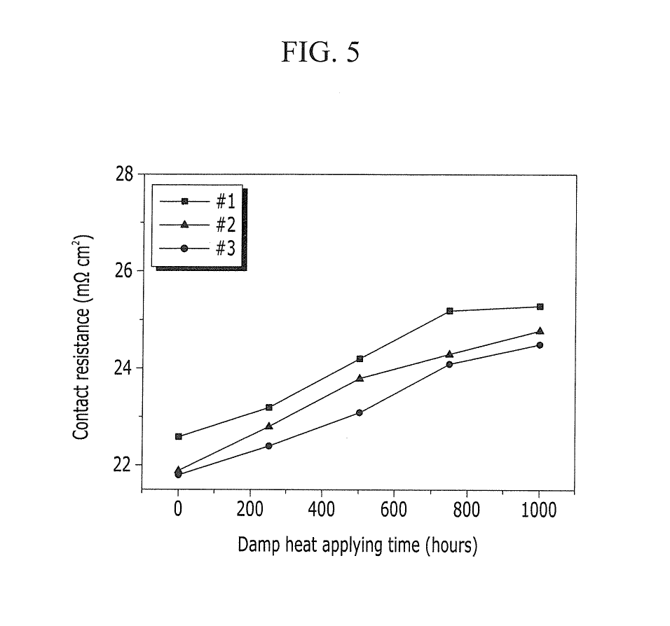

FIG. 5 shows a graph for a damp heat test result for a solar cell module 10 according to an exemplary embodiment. The solar cell module 10 is left alone for about 1000 hours at a 85° C. temperature in an 85% moisture condition, and a charge of the contact resistance is measured. In FIG. 5, #1, #2, and #3 show results acquired by performing the same test and measuring it three times. As shown in FIG. 5, regarding the solar cell module 10 according to the present exemplary embodiment, it is found that the change of the contact resistance is about 2 mΩ/cm² after the damp heat test given for 1000 hours so the change is relatively small. However, when the interconnect wiring 200 is formed with silver paste in the same condition as the present exemplary embodiment, the contact resistance is increased up to 80 mΩ/cm² from the contact resistance of 15 mΩ/cm² after 1000 hours. That is, according to the present exemplary embodiment, the conductive adhesive layer 220 has a structure for protecting the conductive particles by the adhesive layer so it can have excellent reliability against external heat and moisture.

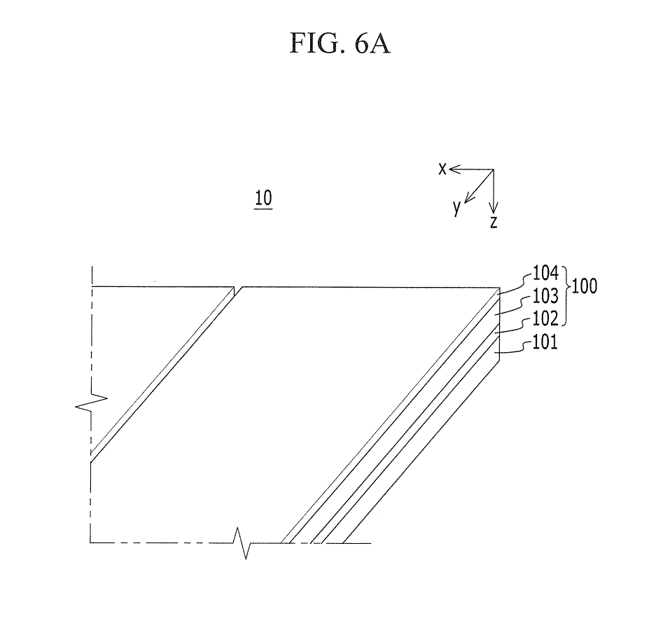

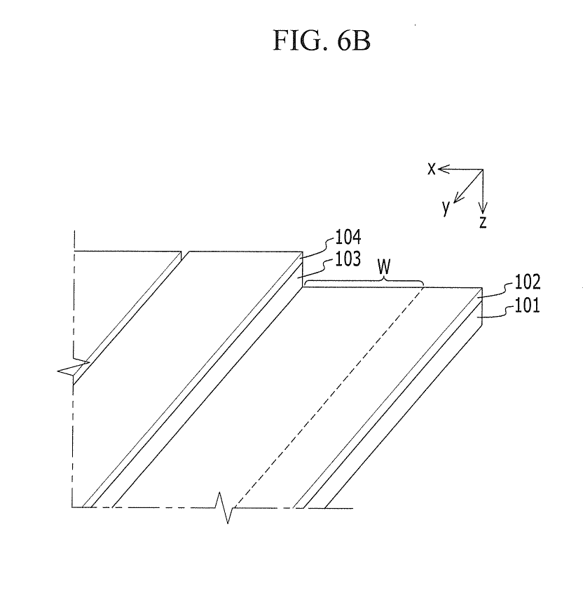

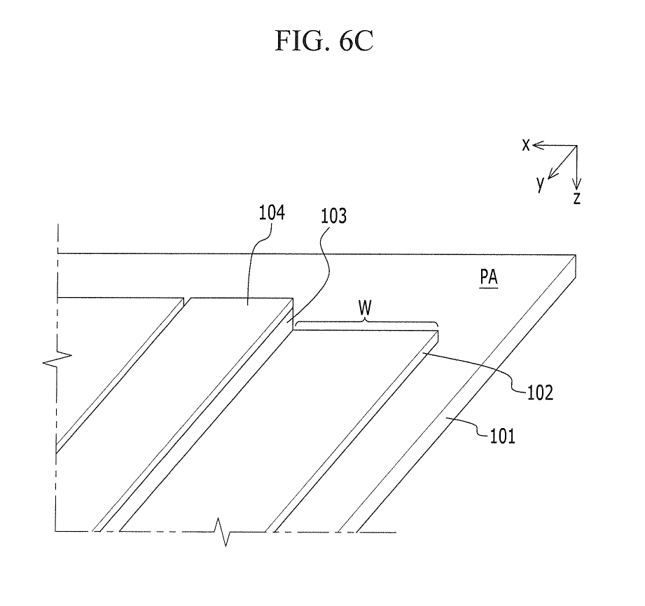

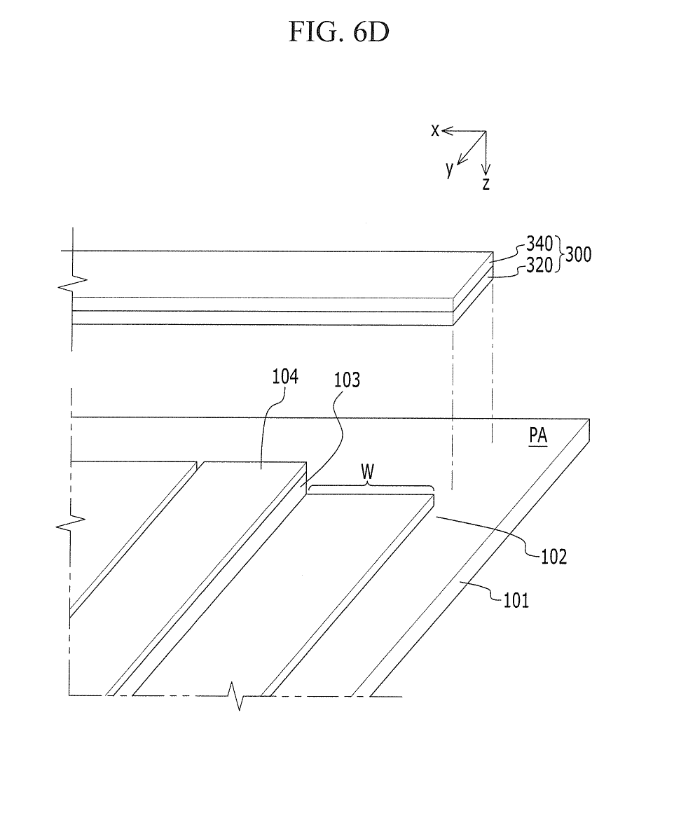

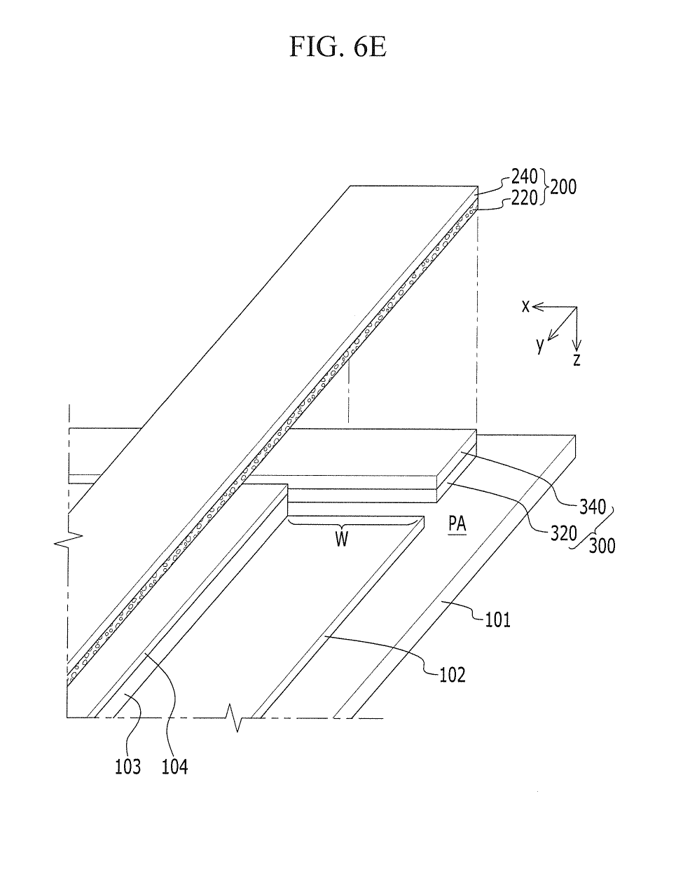

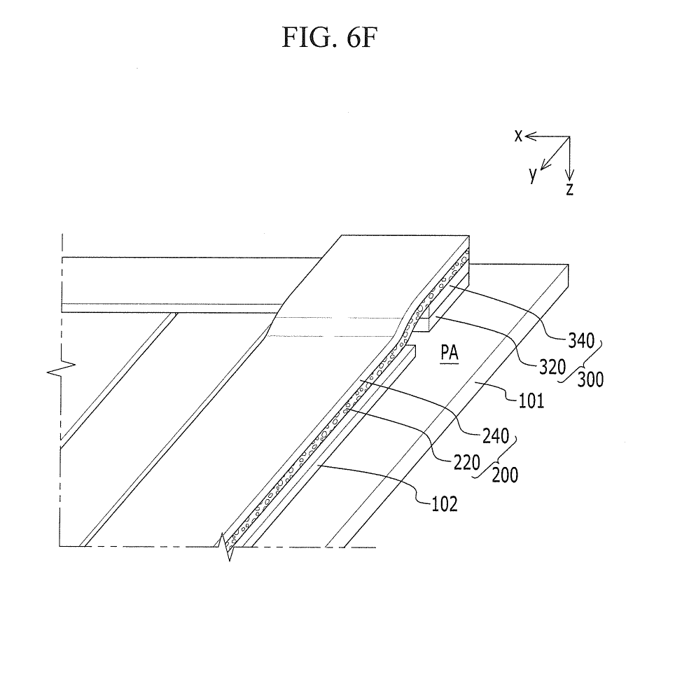

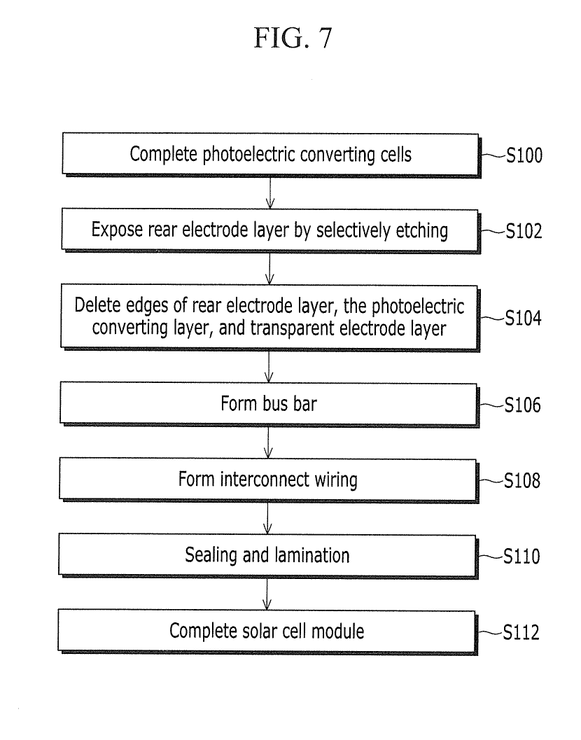

A method for manufacturing a solar cell module 10 according to an exemplary embodiment will now be described with reference to FIG. 6A to FIG. 6F, and FIG. 7. FIG. 6A to 6F show a method for manufacturing a solar cell module according to an exemplary embodiment, magnifying a part V of FIG. 1, and FIG. 7 is a flow chart illustrating the process of a method for fabricating a solar cell module according to an embodiment.

As shown in FIG. 6A, a rear electrode layer 102, a photoelectric converting layer 103, and a transparent electrode layer 104 are sequentially stacked on the substrate 101 and patterned to form a plurality of photoelectric converting cells 100 (S100).

As shown in FIG. 6B, the photoelectric converting layer 103 and the transparent electrode layer 104 of the photoelectric converting cell 100 formed in the outermost region are selectively etched to expose the rear electrode layer 102 (S102). The exposed rear electrode layer 102 includes a wiring connector (W) to which the interconnect wiring 200 is adhered. The selecting etching process may be performed by at least one of the laser scribing method mechanical deletion, wet etching, or paste etching.

As shown in FIG. 6C, the edges of the rear electrode layer 102, the photoelectric converting layer 103, and the transparent electrode layer 104 are removed along an edge of the substrate 101 to expose the substrate 101 (S104). The removed portions correspond to the periphery area (PA). The removal process may be performed by at least one of the laser scribing method mechanical deletion, wet etching, or paste etching.

As shown in FIG. 6D, a bus bar 300 is formed in the periphery area (PA) of the substrate 101 (S106). The bus bar 300 is formed in a direction (x-axis direction of FIG. 6D) that is perpendicular to the length direction of the photoelectric converting cell 100. The bus bar metal layer 340 is adhered to the substrate 101 by using the insulating adhesive layer 320. An opposite first end of the bus bar 300 can be electrically connected to a junction box located outside the solar cell module 10.

As shown in FIG. 6E and FIG. 6F, an interconnect wiring 200 is formed over the wiring connector (W) of the rear electrode layer 102 and the top of the bus bar 300 (S108). The interconnect wiring 200 is formed in a direction (y-axis direction of FIG. 6E) that is generally parallel to the length direction of the photoelectric converting cell 100. The conductive adhesive layer 220 is used to adhere the wiring metal layer 240 to the wiring connector (W) of the rear electrode layer 102. Also, a part that is passed through the wiring connector (W) and is further extended is adhered to the bus bar metal layer 340 of the bus bar 300. Therefore, the wiring metal layer 240 is electrically connected to the rear electrode layer 102 and the bus bar 300 through the conductive particles in the conductive adhesive layer 220. At this time, a pressure process may be performed regarding the interconnect wiring 200 so as to secure a sufficient electrical connection. That is, the rear electrode 102 (or bus bar metal layer 340), the conductive particle, and the wiring metal layer 240 may be contacted and electrically connected to each other by the pressure process. The pressure process may be separately performed when the interconnect wiring 200 is attached, or may be performed with a lamination process (described later) or by pressure of the lamination process.

In addition, if needed, a black cover layer made of a black polyethylene terephthalate (PET) film may be further adhered to the wiring metal layer 240 and the bus bar metal layer 340 so as to improve the appearance. That is, the interconnect wiring 200 with black cover layer thereon is attached to the rear electrode layer 102 and the bus bar 300, and then a tape type black cover layer is attached on the bus bar 300 and the extended portion 201 of the interconnect wiring 200, so that the black cover layer can be formed easily.

Thereafter, a cover substrate is disposed on the solar cell module 10, and then a sealing process and a lamination process is performed (S 110). A frame and a junction box are assembled with the solar cell module 10 to complete the solar cell module 10 (S112).

According to the present exemplary embodiment, the interconnect wiring 200 and the bus bar 300 of the solar cell module 10 may be formed by adhering the metal tape so the cost is reduced and the process is simplified.

Further, the adhesive layer of the interconnect wiring 200 is formed with the conductive adhesive layer 240 and the adhesive layer of the bus bar 300 is formed with the insulating adhesive layer 340, thereby acquiring an excellent characteristic through the simple process. That is, interconnect wiring 200 can have excellent current flow without increasing contact resistance regarding the rear electrode layer 102 and the bus bar 300. In addition, generation of the leakage current by the bus bar 300 is prevented since the bus bar 300 is sufficiently insulated from the substrate 101.

While exemplary embodiments have been described, it is to be understood that the invention is not limited thereto, but is intended to cover various modifications and equivalent arrangements included within the spirit and scope of the appended claims, description, and drawings.

What is claimed is:

1. A solar cell module comprising:
a substrate;
a plurality of photoelectric converting cells;
interconnect wiring electrically coupled to the photoelectric converting cells; and
a bus bar electrically coupled to the interconnect wiring and comprising:
a bus bar metal layer; and
an insulating adhesive layer.

2. The solar cell module of claim 1, wherein a thickness of the insulating adhesive layer is between about 1 μm and about 500 μm.

3. The solar cell module of claim 1, wherein a portion of the interconnect wiring overlaps with a portion of the bus bar to electrically couple the interconnect wiring to the bus bar.

4. The solar cell module of claim 1, wherein the substrate comprises an active area AA in which the photoelectric converting cells are located and a peripheral area PA surrounding the active area and in which the bus bar is located.

5. The solar cell module of claim 1, wherein the insulating adhesive layer comprises a resin.

6. The solar cell module of claim 5, wherein the resin comprises an acryl-based resin, an epoxy-based resin, a butyl-based resin, ethylvinyl acetate, polyvinyl butyral, silicon, an ionomer, or polyoxy ethylene.

7. The solar cell module of claim 1, wherein each of the photoelectric converting cells comprises:
a first electrode layer on the substrate;
a light absorbing layer on the first electrode layer; and
a second electrode layer on the light absorbing layer.

8. The solar cell module of claim 7, wherein the interconnect wiring is on the first electrode layer.

9. The solar cell module of claim 1, wherein the interconnect wiring comprises:
a wiring metal layer; and
a conductive adhesive layer.

10. The solar cell module of claim 9, wherein the conductive adhesive layer comprises conductive particles distributed therein.

11. The solar cell module of claim 10, wherein a diameter of the conductive particles is less than 100 μm.

12. The solar cell module of claim 10, wherein at least some of the conductive particles are electrically coupled to the bus bar metal layer.

13. The solar cell module of claim 9, wherein the conductive adhesive layer comprises a resin.

14. The solar cell module of claim 13, wherein the resin comprises an acryl-based resin, an epoxy-based resin, a butyl-based resin, ethylvinyl acetate, polyvinyl butyral, silicon, an ionomer, or polyoxy ethylene.

15. The solar cell module of claim 9, wherein an overlapping portion of the interconnect wiring overlaps with a portion of the bus bar to electrically couple the interconnect wiring to the bus bar and wherein, in the overlapping portion, the wiring metal layer, the conductive adhesive layer, the bus bar metal layer, and the insulating adhesive layer are sequentially stacked.

16. The solar cell module of claim 9, wherein a thickness of the wiring metal layer is between about 30 μm and about 400 μm.

17. The solar cell module of claim 9, wherein a thickness of the conductive adhesive layer is between about 1 μm and about 500 μm.

18. The solar cell module of claim 1, wherein the bus bar metal layer is spaced from the substrate.

19. A method for manufacturing a solar cell module 10 comprising:
stacking together a first electrode layer, a photoelectric converting layer, and a second electrode layer on a substrate;
etching the photoelectric converting layer and the second electrode layer to expose the first electrode layer;
removing an edge of the first electrode layer to expose the substrate;
adhering a bus bar to the substrate using an insulating adhesive layer; and
electrically coupling an interconnect wiring to the bus bar such that an overlapping portion of the interconnect wiring is on top of the bus bar.

20. The method of claim 19, wherein the interconnect wiring comprises a wiring metal layer and a conductive adhesive layer and wherein the bus bar comprises a bus bar metal layer and the insulating adhesive layer, wherein the conductive adhesive layer is coupled to the bus bar metal layer at the overlapping portion.
